(19) United States
(12) Patent Application Publication
(10) Pub. No.: US 2024/0136207 A1
(43) Pub. Date: Apr. 25, 2024

(54) HEAT SOURCE ARRANGEMENTS, PROCESSING CHAMBERS, AND RELATED METHODS TO FACILITATE DEPOSITION PROCESS ADJUSTABILITY

(71) Applicant: Applied Materials, Inc., Santa Clara, CA (US)

(72) Inventors: Ala MORADIAN, Sunnyvale, CA (US); Saurabh CHOPRA, Santa Clara, CA (US)

(21) Appl. No.: 17/971,338

(22) Filed: Oct. 20, 2022

(51) Int. Cl. H01L 21/67

(52) U.S. Cl. CPC H01L 21/67115; H01L 21/67207

(57) ABSTRACT

The present disclosure relates to heat source arrangements, processing chambers, and related methods to facilitate deposition process adjustability. In one implementation, a processing chamber applicable for use in semiconductor manufacturing includes a lower window and an upper window. The lower window and the upper window at least partially define an internal volume. The processing chamber includes a substrate support disposed in the internal volume, and the substrate support includes a support face. The processing chamber includes one or more inner heat sources. Each inner heat source of the one or more inner heat sources is oriented substantially parallel to a surface of the support face. The processing chamber includes one or more outer heat sources disposed outwardly of the inner heat sources. Each outer heat source of the one or more outer heat sources is oriented nonparallel to the surface of the support face.

### BACKGROUND

### Field

The present disclosure relates to heat source arrangements, processing chambers, and related methods to facilitate deposition process adjustability.

### Description of the Related Art

Semiconductor substrates are processed for a wide variety of applications, including the fabrication of integrated devices and microdevices. During processing, various parameters can affect the uniformity of material deposited on the substrate. Quality and consistency (e.g., of an epitaxial layer) can depend on precise temperature and flow control inside the chamber. For example, the temperature of the substrate and/or temperature(s) of processing chamber component(s) can affect deposition uniformity.

Hence, temperature non-uniformities can affect deposition uniformity, particularly after adjustment of parameters (such as temperature, pressure, and gas flow rates). It can be difficult to adjust parameters (such as temperatures, gas flow rates, and gas pressures) for deposition uniformity. As an example, it can be difficult to adjust the temperature of an outer portion of a substrate without unintentionally affecting the temperature of other portion(s) of the substrate and/or components of the chamber. Rotation of the substrate, if used, can exacerbate adjustment difficulties. Relatively low rotation speeds, high pressures, and low flow rates can also exacerbate adjustment difficulties.

Therefore, a need exists for improved processing chambers and related methods that facilitate parameter uniformity and adjusting process parameters (such as temperature).

### SUMMARY

The present disclosure relates to heat source arrangements, processing chambers, and related methods to facilitate deposition process adjustability, such as for silicon substrates.

In one implementation, a processing chamber applicable for use in semiconductor manufacturing includes a lower window and an upper window. The lower window and the upper window at least partially define an internal volume. The processing chamber includes a substrate support disposed in the internal volume, and the substrate support includes a support face. The processing chamber includes one or more inner heat sources. Each inner heat source of the one or more inner heat sources is oriented substantially parallel to a surface of the support face. The processing chamber includes one or more outer heat sources disposed outwardly of the one or more inner heat sources. Each outer heat source of the one or more outer heat sources is oriented nonparallel to the surface of the support face.

In one implementation, a processing chamber applicable for use in semiconductor manufacturing includes a lower window and an upper window. The lower window and the upper window at least partially define an internal volume. The processing chamber includes a substrate support disposed in the internal volume. The substrate support includes an outer radius and a support face. The processing chamber includes one or more heat sources. Each heat source of the one or more heat sources is aligned at an offset relative to a center of the substrate support. The offset is a ratio of the outer radius, and the ratio is 0.65 or higher.

In one implementation, a method of processing substrates includes heating a substrate positioned on a substrate support in a processing volume of a chamber. The heating includes directing radial light radially outward relative to one or more inner heat sources and toward an inner portion of the substrate, and directing linear light linearly relative to one or more outer heat sources and toward an outer portion of the substrate. The method includes flowing one or more process gases over the substrate to form one or more layers on the substrate, and exhausting the one or more process gases.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic side cross-sectional view of a processing chamber, according to one implementation.

FIG. 2 is a schematic enlarged view of the processing chamber shown in FIG. 1, according to one implementation.

FIG. 3 is a schematic side cross-sectional view of a processing chamber, according to one implementation.

FIG. 4 is a schematic partial top view of the processing chamber shown in FIG. 3, according to one implementation.

FIG. 5 is a schematic partial top view of the processing chamber shown in FIG. 3, according to one implementation.

FIG. 6 is a schematic side cross-sectional view of a processing chamber, according to one implementation.

FIG. 7 is a schematic block diagram view of a method of processing substrates, according to one implementation.

FIG. 8 is a schematic graphical view of a graph showing normalized irradiance versus location (in mm) horizontally in the processing chamber, according to one implementation.

FIG. 9 is a schematic diagram view of one of the lower outer heat sources shown in FIG. 3, according to one implementation.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to heat source arrangements, processing chambers, and related methods to facilitate deposition process adjustability.

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links.

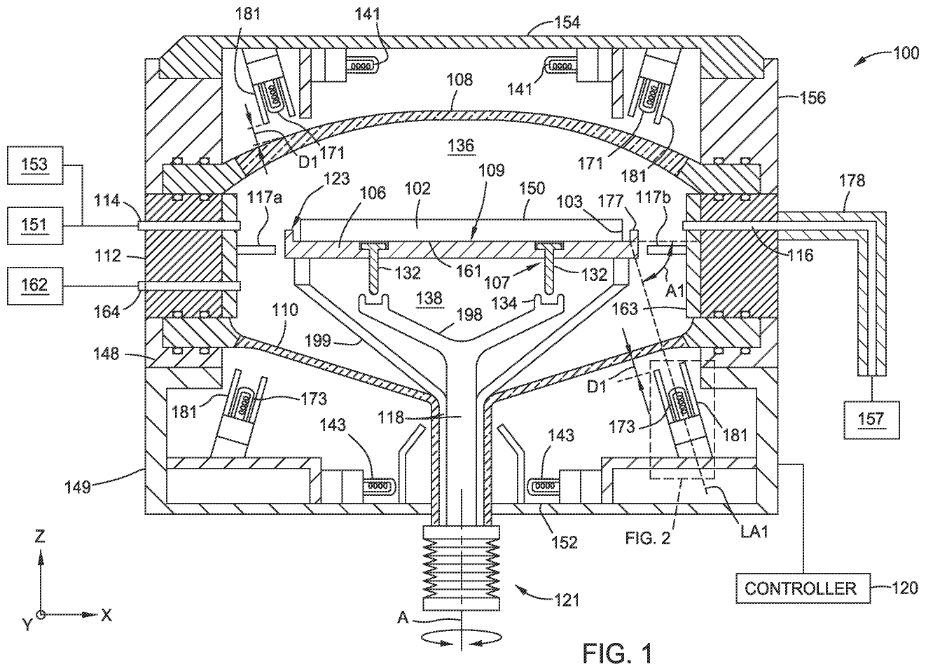

FIG. 1 is a schematic side cross-sectional view of a processing chamber 100, according to one implementation. The processing chamber 100 is a deposition chamber. In one embodiment, which can be combined with other embodiments, the processing chamber 100 is an epitaxial deposition chamber. The processing chamber 100 is utilized to grow an epitaxial film on a substrate 102. The processing chamber 100 creates a cross-flow of precursors across a top surface 150 of the substrate 102.

The processing chamber 100 includes an upper body 156, a lower body 148 disposed below the upper body 156, a flow module 112 disposed between the upper body 156 and the lower body 148. In one or more embodiments, the upper body 156 includes an upper clamp ring and the lower body 148 includes a lower clamp ring. In one or more embodiments, the flow module 112 includes a base ring. The processing chamber 100 includes an upper reflector structure 154 and a lower reflector structure 149 (the reflector structures 154, 149 can each be referred to as a heat shield). The upper body 156, the flow module 112, the lower body 148, the upper reflector structure 154 and the lower reflector structure 149 form a chamber body.

Disposed within the chamber body is a substrate support 106, an upper window 108 (such as an upper dome), a lower window 110 (such as a lower dome), a plurality of upper heat sources 141, 171 and a plurality of lower heat sources 143, 173. The present disclosure contemplates that each upper heat source 141, 171 and each lower heat source 143, 173 can include a heat lamp, a side resistive heater, a light emitted diode (LED), and/or a laser, for example. In one or more embodiments, each upper heat source 141, 171 and each lower heat source 143, 173 includes a lamp configured to emit infrared radiation (IR) light.

As shown, a controller 120 is in communication with the processing chamber 100 and is used to control processes and methods, such as the operations of the methods described herein. The substrate support 106 has a support face 109 that supports the substrate 102.

The substrate support 106 is disposed between the upper window 108 and the lower window 110. The substrate support 106 includes a support face 123 that supports the substrate 102. The plurality of upper heat sources 141, 171 are disposed between the upper window and the upper reflector structure 154. The upper reflector structure 154 can be part of a lid. The upper reflector structure 154 may include a plurality of sensors (not shown) disposed therein or thereon for measuring the temperature within the processing chamber 100.

A reflective coating is formed on one or more inner surfaces of the upper reflector structure 154 and one or more inner surfaces of the lower reflector structure 149. The reflective coating can be similar to or the same as the inner coating 183 described below.

The plurality of lower heat sources 143, 173 are disposed between the lower window 110 and a floor 152. The upper window 108 is an upper dome and is formed of an energy transmissive material, such as quartz. The lower window 110 is a lower dome and is formed of an energy transmissive material, such as quartz. In one or more embodiments, each of the windows 108, 110 is formed of a materials that is at least 95% transmissive for light having a wavelength in the infrared (IR) range.

A process volume 136 and a purge volume 138 are formed between the upper window 108 and the lower window 110. The process volume 136 and the purge volume 138 are part of an internal volume defined at least partially by the upper window 108, the lower window 110, and the one or more liners 163.

The internal volume has the substrate support 106 disposed therein. The substrate support 106 includes a surface 161 on which the substrate 102 is disposed, and an outer shoulder 165 that surrounds the surface 161. The processing chamber includes a first support frame 198 and a second support frame 199 disposed at least partially about the first support frame 198. The second support frame 199 includes arms coupled to the substrate support 106 such that lifting and lowering the second support frame 199 lifts and lowers the substrate support 106. A plurality of lift pins 132 are suspended from the substrate support 106. Lowering of the substrate support 106 initiates contact of the lift pins 132 with arms of the first support frame 198. Continued lowering of the substrate support 106 initiates contact of the lift pins 132 with the substrate 102 such that the lift pins 132 raise the substrate 102. A stem 118 (such as a shaft) of each support frame 198, 199 extends through a bottom of the lower body 148.

The substrate support 106 is attached to the stem 118 of the second support frame 199 through the arms. The stem 118 of each support frame 198, 199 is connected to a motion assembly 121. The motion assembly 121 includes one or more actuators and/or adjustment devices that provide movement and/or adjustment for the support frames 198, 199 within the processing volume 136. The substrate support 106 may include lift pin holes 107 disposed therein. The lift pin holes 107 are each sized to accommodate a respective lift pin 132 of the lift pins 132 for lifting of the substrate 102 from the substrate support 106 before or after a deposition process is performed. The lift pins 132 may rest on lift pin stops 134 when the substrate support 106 is lowered from a process position to a transfer position. In the implementation shown in FIG. 1, the lift pin stops 134 are part of the arms of the first support frame 198.

The flow module 112 includes a plurality of gas inlets 114, a plurality of purge gas inlets 164, and one or more gas exhaust outlets 116. The plurality of gas inlets 114 and the plurality of purge gas inlets 164 are disposed on the opposite side of the flow module 112 from the one or more gas exhaust outlets 116. One or more flow guides 117a, 117b are disposed below the plurality of gas inlets 114 and the one or more gas exhaust outlets 116. The one or more flow guides 117a, 117b are disposed above the purge gas inlets 164. In one or more embodiments, the one or more flow guides 117A, 117B are integrated as a pre-heat ring. One or more liners 163 are disposed on an inner surface of the flow module 112 and protects the flow module 112 from reactive gases used during deposition operations and/or cleaning operations. The gas inlet(s) 114 and the purge gas inlet(s) 164 are each positioned to flow a gas parallel to the top surface 150 of a substrate 102 disposed within the process volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. One or more process gases supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). One or more purge gases supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen (H) and/or chlorine (Cl). In one embodiment, which can be combined with other embodiments, the one or more process gases include silicon phosphide (SiP) and/or phosphine (PH₃), and the one or more cleaning gases include hydrochloric acid (HCl).

The one or more gas exhaust outlets 116 are further connected to or include an exhaust system 178. The exhaust system 178 fluidly connects the one or more gas exhaust outlets 116 to the exhaust pump 157. The exhaust system 178 can assist in the controlled deposition of a layer on the substrate 102. The exhaust system 178 is disposed on an opposite side of the processing chamber 100 relative to the flow module 112.

The controller 120 includes a central processing unit (CPU), a memory containing instructions, and support circuits for the CPU. The controller 120 controls various items directly, or via other computers and/or controllers. In one or more embodiments, the controller 120 is communicatively coupled to dedicated controllers, and the controller 120 functions as a central controller.

The controller 120 is of any form of a general-purpose computer processor that is used in an industrial setting for controlling various substrate processing chambers and equipment, and sub-processors thereon or therein. The memory, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits of the controller 120 are coupled to the CPU for supporting the CPU (a processor). The support circuits include cache, power supplies, clock circuits, input/output circuitry and subsystems, and the like. Operational parameters (such as heating powers applied to individual heat sources (e.g., lamps), pressure for process gas, a flow rate for process gas, and/or a rotational position of the substrate support 106) and operations are stored in the memory as a software routine that is executed or invoked to turn the controller 120 into a specific purpose controller to control the operations of the various chambers/modules described herein. The controller 120 is configured to conduct any of the operations described herein. The instructions stored on the memory, when executed, cause one or more of the operations (such as the operations 602, 604, 606 of the method 600) described herein to be conducted.

The various operations described herein can be conducted automatically using the controller 120, or can be conducted automatically or manually with certain operations conducted by a user.

The processing chamber 100 includes a plurality of inner heat sources 141, 143. Each inner heat source 141, 143 of the plurality of inner heat sources 141, 143 is oriented substantially parallel to the surface 161 of the support face 123 such that a longitudinal axis of each inner heat source 141, 143 is oriented at a difference of 5 degrees or less relative to a plane of the surface 161. In one or more embodiments, the difference is 0 degrees such that each inner heat source 141, 143 is parallel to the surface 161. The plurality of inner heat sources 141, 143 include a first set of inner heat sources 143 below the lower window 110 and a second set of inner heat sources 141 above the upper window 108. The present disclosure contemplates that the inner heat sources 141, 143 could be oriented nonparallel to the surface 161 such that the longitudinal axis of each inner heat source 141, 143 is oriented at a difference of more than 5 degrees relative to the plane of the surface 161.

The processing chamber 100 includes a plurality of outer heat sources 171, 173 disposed outwardly of the inner heat sources 141, 171. Each outer heat source 171, 173 of the plurality of outer heat sources 171, 173 is oriented nonparallel to the surface 161 of the support face 123 such that a longitudinal axis LA1 of each outer heat source 171, 173 is more than 5 degrees relative to the plane of the surface 161. The plurality of outer heat sources 171, 173 include a first set of outer heat sources 173 below the lower window 110 and a second set of outer heat sources 171 above the upper window 108. The longitudinal axis LA1 of each outer heat source 171, 173 of the plurality of outer heat sources 171, 173 is oriented at an angle A1 relative to the surface 161 of the support face 123. The angle A1 is within a range of 65 degrees to 90 degrees. The present disclosure contemplates that the first set of outer heat sources 173 or the second set of outer heat sources 171 can be omitted.

In one or more embodiments, the first set of inner heat sources 143 are configured to heat an inner portion of the substrate 102 on a back side of the substrate 102 (e.g., a back inner zone) using radial light directed to the substrate 102. The inner portion can include a center of the substrate 102. The second set of inner heat sources 141 are configured to heat the inner portion of the substrate 102 on a front side of the substrate 102 (e.g., a front inner zone) using radial light directed to the substrate 102.

first set of outer heat sources 173 below the lower window 110 and a second set of outer heat sources 171

In one or more embodiments, the first set of outer heat sources 173 are configured to heat an outer portion of the substrate 102 on a back side of the substrate 102 (e.g., a back outer zone) using linear light directed to the substrate 102. The outer portion of the substrate 102 includes an outer edge 103 of the substrate 102. The second set of outer heat sources 171 are configured to heat the outer portion of the substrate 102 (which includes the outer edge 103) on a front side of the substrate 102 (e.g., a front outer zone) using linear light directed to the substrate 102.

Each outer heat source 171, 173 of the plurality of heat sources 171, 173 is directed toward one or more of the substrate support 106, a pre-heat ring 117A, 117B disposed outwardly of the substrate support 106, and/or one or more liners 163 disposed outwardly of the substrate support 106. In one or more embodiments, each outer heat source 171, 173 is directed such that each longitudinal axis LA1 is directed to extend through one or more of the surface 161 that supports the substrate 102, the outer shoulder 177 and/or a space between the substrate 102 and the outer shoulder 177. In one or more embodiments, each outer heat source 171, 173 is directed such that each longitudinal axis LA1 is directed to extend through one or more of the pre-heat ring 117A, 117B and/or the one or more liners 163.

A reflective sleeve 181 disposed about each outer heat source 171, 173 of the plurality of outer heat sources 171, 173. An end of each reflective sleeve 181 is disposed at a distance D1 relative to the nearest of the lower window 110 or the upper window 108. In one or more embodiments, the distance D1 is 10 mm or higher. The end of each reflective sleeve 181 extends past an end of the respective outer heat source 171, 173 (such as past an end of the bulb of the respective outer heat sources 171, 173. The reflective sleeves 181 facilitate directing light linearly toward the outer portion of the substrate 102 for targeted heating.

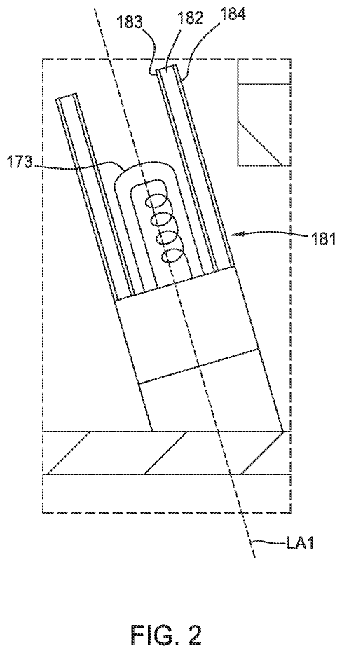

FIG. 2 is a schematic enlarged view of the processing chamber 100 shown in FIG. 1, according to one implementation. In one or more embodiments, each outer heat sources 171, 173 includes a lamp, and the longitudinal axis LA1 extends through the coils of a filament of the lamp.

Each reflective sleeve 181 includes a base material 182 and an inner coating 183. The inner coating 183 has a reflectivity that is 0.8 or higher. In one or more embodiments, the inner coating 183 includes one or more of: gold (Au), silver (Ag), and/or one or more ceramics. Other materials are contemplated for the inner coating 183. In one or more embodiments, the base material 182 includes a metal such as aluminum or stainless steel. Other materials are contemplated for the base material 182 and the coatings 183, 184. The material(s) for the base metal 182 and/or the material(s) for the coatings 183, 184 can be affected by the processing temperature used during processing (e.g., deposition). In one or more embodiments, each reflective sleeve 181 includes an outer coating 184 that is similar to or identical to the inner coating 183. The base material 182 has a thickness T1 that is within a range of 1.0 mm to 5.00 mm. In one or more embodiments, the thickness T1 is within a range of 1.8 mm to 2.2 mm, such as 2.0 mm. Each of the inner coating 183 and the outer coating 184 has a thickness T2 that is within a range of 80 microns to 150 microns. In or more embodiments, the thickness T2 of each coating 183, 184 is within a range of 95 microns to 105 microns, such as 100 microns.

The present disclosure contemplates that a polished surface (such as a mirror-polished surface) can be used in place of the inner coating 183, the outer coating 184, and/or the reflective coating discussed above. As an example, inner surface(s) and/or outer surface(s) of the base material 182 can be mirror-polished.

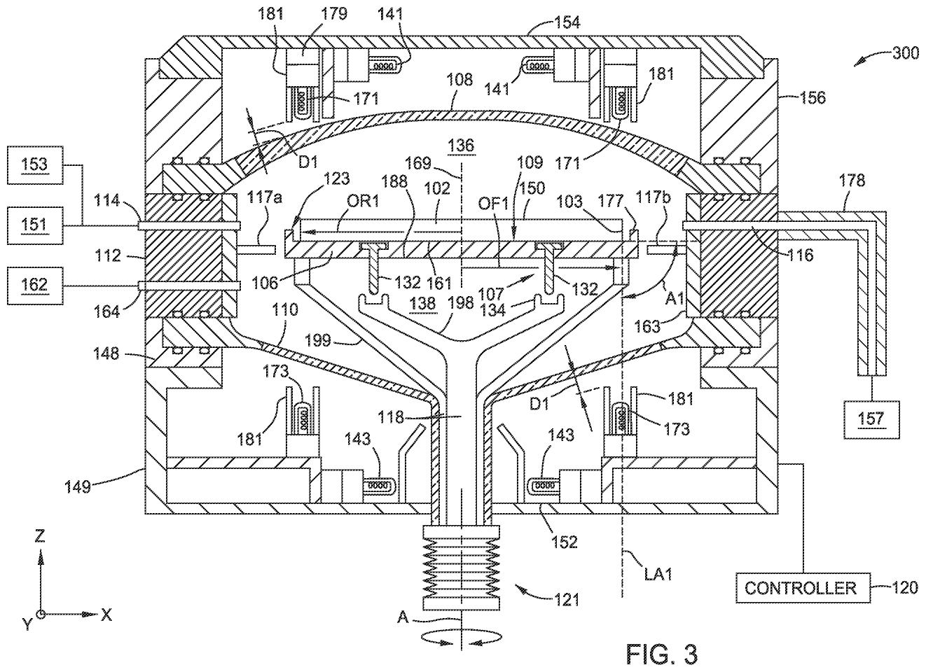

FIG. 3 is a schematic side cross-sectional view of a processing chamber 300, according to one implementation. The processing chamber 300 is similar to the processing chamber 100, and includes one or more of the aspects, features, operations, components, and/or properties thereof.

The substrate support 106 has an outer radius OR1. As described above, each outer heat source 171, 173 of the plurality of heat sources 171, 173 is oriented nonparallel to the surface 161 of the support face 123. In one or more embodiments, each outer heat source 171, 173 is oriented substantially perpendicular to the surface 161 such that the angle A1 is within a range of 85 degrees to 90 degrees. Each outer heat source 171, 173 of the plurality of heat sources 171, 173 is aligned at an offset OF1 relative to a center 169 of the substrate support 106. The offset OF1 is a ratio of the outer radius OR1. The ratio is 0.65 or higher. In one or more embodiments, the ratio is 0.7 or higher. In one or more embodiments, the ratio is 0.8 or higher, such as 1.0 or higher. In one or more embodiments, the ratio is within a range of 0.65 to 1.35.

In the implementation shown in FIG. 3, each inner heat source 141, 143 is oriented horizontally and each outer heat source 171, 173 is oriented vertically.

In the implementation shown in FIG. 3, each outer heat source 171, 173 is positioned such that each longitudinal axis LA1 is aligned with the outer edge 103 of the substrate 102. In one or more embodiments, each outer heat source 171, 173 shown can be moved horizontally such that each vertical longitudinal axis LA1 can be aligned outwardly of the outer edge 103, such as aligned with the pre-heat ring 117A, 117B, the one or more liners 163, and/or the flow module 112 (which can be part of one or more sidewalls of the processing chamber 300). As an example, the longitudinal axes LA1 can be oriented to heat sidewalls of the processing chamber 300, the one or more liners 163, and/or process gases (such as precursor gases).

The present disclosure contemplates that one of the upper outer heat sources 171 or the lower outer heat sources 173 can be aligned with the outer edge 103 (e.g., vertically as in FIG. 3 or at an angle as in FIGS. 1 and 2), and the other of the upper outer heat sources 171 or the lower outer heat sources 173 can be aligned outwardly of the outer edge 171 (e.g., vertically as in FIG. 3 or at an angle as in FIGS. 1 and 2). For example, the upper outer heat sources 171 can be aligned with the outer edge 103 and the lower outer heat sources 173 and be aligned with the pre-heat ring 117a, 117b, the one or more liners 163, and/or the flow module 112.

The present disclosure contemplates that the outer heat sources 171, 173 can include various forms of heat sources. For example, the upper outer heat sources 171 can include lasers, LEDs, and/or resistive heaters, and the lower outer heat sources 173 can include lamps.

One or more (such as all) of the outer heat sources 171, 173 is linearly movable using a base motor 179. Each base motor 179 can include, for example, a linear actuator (such as an electric actuator). An individual base motor 179 can be used for each outer heat sources 171, 173 or a plurality of the heat sources 171, 173 can be mounted to a common plate that is moved by base motor(s) 179. The linear positions of the outer heat sources 171, 173 can be affected by (and controlled accordingly by the controller 120) a process recipe.

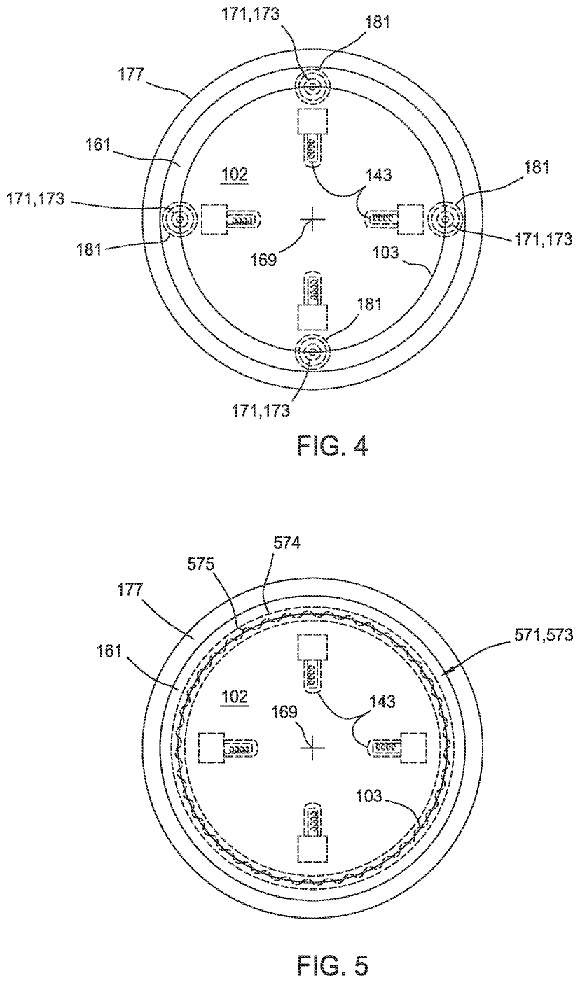

FIG. 4 is a schematic partial top view of the processing chamber 300 shown in FIG. 3, according to one implementation.

Each of the first set of outer heat sources 173 and the second set of outer heat sources 171 includes four heat sources. Various other numbers of heat sources (such as one or two) are contemplated for each set of outer heat sources.

Each of first set of inner heat sources 143 and the second set of inner heat sources 141 includes four heat sources. Various other numbers of heat sources (such as one or two) are contemplated for each set of inner heat sources.

The number of heat sources discussed herein can be influenced, for example, by a temperature recipe for processing.

FIG. 5 is a schematic partial top view of the processing chamber 300 shown in FIG. 3, according to one implementation.

In the implementation shown in FIG. 5, each of the first set of outer heat sources 173 and the second set of outer heat sources 171 is replaced with an arcuate heat source 571, 573 (such as an arcuate lamp) such that a first arcuate heat source 573 is below the lower window 110 and a second arcuate heat source 571 is above the upper window 108. Each arcuate heat source 571, 573 is curvilinear and can be a circular heat source (such as a circular lamp). In one or more embodiments, each arcuate heat source 571, 573 includes a cylindrical bulb tube 574 and a filament 575 extending along an arc (such as a circle). Each cylindrical bulb tube 574 can be a single tube for each arcuate heat source 571, 573, or can be a plurality of arcuate segments. Each filament 575 can be a single filament for each arcuate heat source 517, 573, or can be a plurality of arcuate segments. In the implementation shown in FIG. 5, a longitudinal axis of the filament 575 (and the cylindrical bulb tube 574) is aligned with and parallel to the outer edge 103 of the substrate 102. The longitudinal axis of the filament 575 (and the cylindrical bulb tube 574) can be positioned at the offset OF1. The present disclosure contemplates that one of the arcuate heat sources 571, 573 can be omitted.

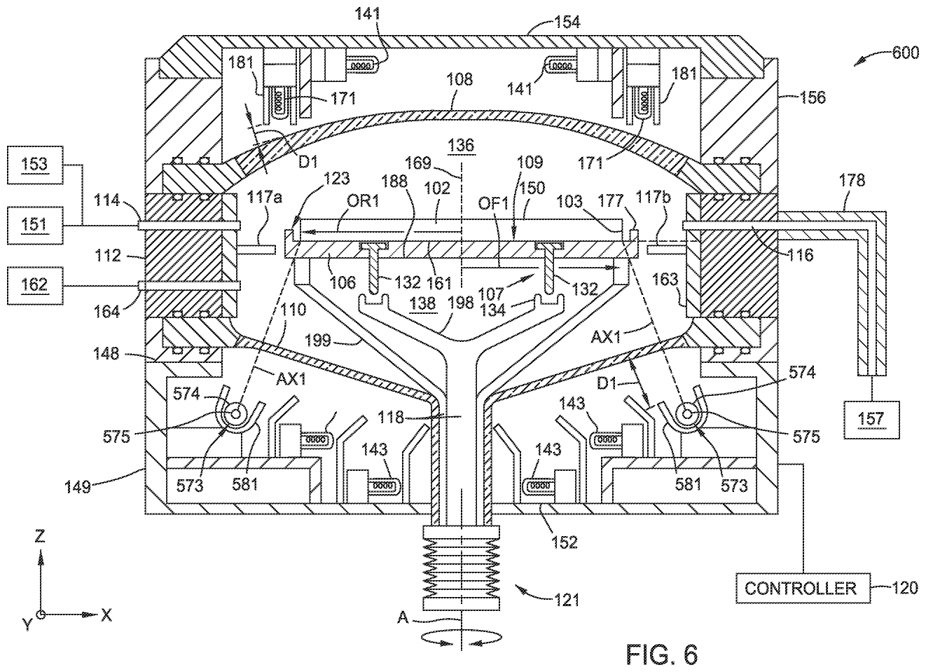

FIG. 6 is a schematic side cross-sectional view of a processing chamber 600, according to one implementation. The processing chamber 600 is similar to the processing chambers 100, 300, and can include one or more of the aspects, features, components, operations, and/or properties thereof.

In the implementation shown in FIG. 6, one or more outer arcuate heat sources 571 are disposed below the lower window 110. One or more reflective segments 581 are disposed partially about each of the one or more outer arcuate heat sources 571. The one or more reflective segments 581 can be similar to the reflective segments 181, and can include one or more aspects, features, components, operations, and/or properties thereof. The one or more reflective segments 581 direct heat (e.g., light) along axes AX1. In the implementation shown in FIG. 6, the axes AX1 are directed toward the outer edge 103. Other directions are contemplated for the axes AX1, as discussed herein. Each of the one or more reflective segments 581 is curvilinear and has a cross-section that is parabolic in shape.

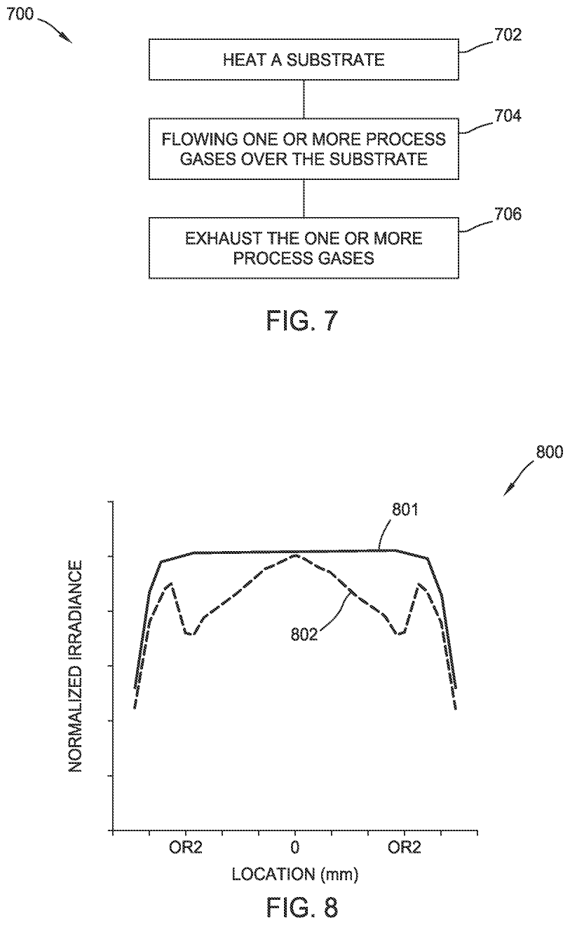

FIG. 7 is a schematic block diagram view of a method 700 of processing substrates, according to one implementation.

At operation 702, the method 700 includes heating a substrate positioned on a substrate support in a processing volume of a chamber. The heating includes directing radial light radially outward relative to one or more inner heat sources and toward an inner portion of the substrate. The radial light is directed radially outwardly relative to a bulb of each inner heat source of the one or more inner heat sources.

The heating also includes directing linear light linearly relative to one or more outer heat sources and toward an outer portion of the substrate. The outer portion includes an outer edge of the substrate. The linear light is directed linearly along a linear axis of a filament of each outer heat source of the one or more outer heat sources.

Operation 704 includes flowing one or more process gases over the substrate to form one or more layers on the substrate.

The method 700 can include rotating the substrate (e.g., using the substrate support) while heating the substrate and/or flowing the one or more process gases.

Operation 706 includes exhausting the one or more process gases.

FIG. 8 is a schematic graphical view of a graph 800 showing normalized irradiance versus location (in mm) horizontally in the processing chamber, according to one implementation. The zero value for the location corresponds to the center 169 of the substrate support 106. An outer radius OR2 is the outer radius of the substrate 102.

A first profile 801 shows the normalized irradiance of a processing chamber having subject matter described herein.

A second profile 802 shows the normalized irradiance of a processing chamber according to another configuration.

As shown by comparing the first profile 801 with the second profile 802, it is believed that the first profile 801 involves a more uniform irradiance (and hence more uniform temperature profile and more uniform deposition thickness). For example, it is believed that the first profile 801 shows an irradiance at the outer radius OR2 (e.g., at the outer edge 103) that is more uniform with the center of the substrate, relative to the second profile 802. The uniformity facilitates adjustability of processing parameters, such as a temperature at the outer portion of the substrate 102 (e.g., at the outer edge 103).

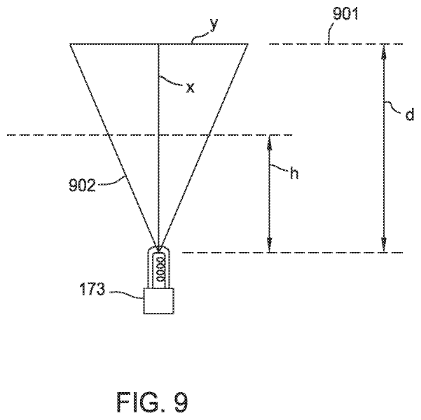

FIG. 9 is a schematic diagram view of one of the lower outer heat sources 173 shown in FIG. 3, according to one implementation. The heat source 173 is linearly movable (e.g., using a base motor 179 described above).

As the heat source(s) move in relation to a plane 901 (defined by a backside 188 of the substrate support 106), a cone 902 of irradiation and an irradiance intensity of the irradiation changes. As the heat source(s) move closer to the plane 901 (such that a distance (d) decreases), a width (y) of the cone 902 decreases and the irradiance intensity increases. As the heat source(s) move farther from the plane 901 the width (y) of the cone 902 increases and the irradiance intensity decreases. A height (x) is equal to the distance (d). An incident irradiance power intensity (Iy) can be determined using the following Equation 1:

$$Iy = {Ip ( \frac{h}{d} )}^{2}$$

Ip is a peak intensity for the heat source(s)). A factor (h) can be determined using the following Equation 2:

$$h = \frac{x * d}{y}$$

The controller 120 can use, for example, Equations 1 and 2 to determine a distance (d) to which the heat source(s) are linearly moved to facilitate achieving a target incident irradiance power intensity (Iy) during processing. The target incident irradiance power intensity (Iy) can be determined by the controller 120, for example, from a processing recipe. Such a method facilitates irradiance intensity adjustability for temperature adjustability (e.g., at an outer portion of the substrate support 106 and/or the outer portion of the substrate 102)

Benefits of the present disclosure include reducing or eliminating temperature non-uniformities; enhanced center-to-edge deposition uniformity; adjustability (and uniformity) of processing parameters (such as temperature, pressure, and gas flow rates), such as at outer portions of substrates that include the outer edges; accurately adjusting processing temperatures of portions of substrates (including during rotation of the substrate); reduced heat loss and power consumption; modularity of adjustability; and targeted heating.

As an example, the ratio described herein and/or the configurations of the inner heat sources 141, 143, the outer heat sources 171, 173, the outer heat sources 571, 573, the reflective sleeves 181, and/or the reflective sleeves 581 facilitate accurately adjusting the heating (e.g., the temperature) of the outer portion of the substrate 102 (including the outer edge 103) relative to the inner portion and other chamber components. Such adjustability is facilitated while facilitating reduced or eliminated heat loss to other chamber components, reduced or eliminated power waste, and reduced or eliminated power expenditure.

As another example, the implementations of the present disclosure are modular and can be used across a variety of processing (e.g., deposition) operations and/or cleaning operations, including across a variety of operation parameters.

It is contemplated that one or more aspects disclosed herein may be combined. As an example, one or more aspects, features, components, operations, and/or properties of the processing chamber 100, the heat source configurations shown in FIGS. 1 and 2, the processing chamber 300, the heat source configurations shown in FIGS. 3 and 4, the outer heat sources 571, 573, the heat source configurations shown in FIGS. 3 and 6, the reflective segments 581, the method 700, and/or the methods of FIG. 9 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A processing chamber applicable for use in semiconductor manufacturing, comprising:
a lower window;
an upper window, the lower window and the upper window at least partially defining an internal volume;
a substrate support disposed in the internal volume, the substrate support comprising a support face;
one or more inner heat sources, each inner heat source of the one or more inner heat sources oriented substantially parallel to a surface of the support face; and
one or more outer heat sources disposed outwardly of the one or more inner heat sources, each outer heat source of the one or more outer heat sources oriented nonparallel to the surface of the support face.

2. The processing chamber of claim 1, wherein:
the one or more inner heat sources comprise a first set of inner heat sources below the lower window and a second set of inner heat sources above the upper window;
the one or more outer heat sources comprise a first set of outer heat sources below the lower window and a second set of outer heat sources above the upper window; and
each inner heat source and each outer heat source includes a lamp configured to emit infrared radiation (IR) light.

3. The processing chamber of claim 1, wherein each outer heat source of the one or more outer heat sources is oriented at an angle relative to the surface of the support face.

4. The processing chamber of claim 3, wherein the angle is within a range of 65 degrees to 90 degrees.

5. The processing chamber of claim 1, wherein a reflective sleeve is disposed about each outer heat source of the one or more outer heat sources.

6. The processing chamber of claim 5, wherein each reflective sleeve comprises a base material and an inner coating.

7. The processing chamber of claim 6, wherein the base material includes stainless steel or aluminum, and the inner coating includes one or more of: gold (Au), silver (Ag), and/or one or more ceramics.

8. The processing chamber of claim 6, wherein an end of each reflective sleeve is disposed at a distance relative to the nearest of the lower window or the upper window, and the distance is 10 mm or higher,

9. The processing chamber of claim 1, wherein each outer heat source of the one or more outer heat sources is linearly movable using a base motor.

10. The processing chamber of claim 1, wherein the one or more outer heat sources comprise:
a first set of one or more outer heat sources above the upper window, wherein:
each heat source of the first set includes a laser, a light emitted diode (LED) or a resistive heater, and
each heat source of the first set is directed toward the substrate support; and
a second set of one or more outer heat sources below the lower window, wherein:
each heat source of the second set includes a lamp, and
each heat source of the second set is directed toward one or more of a pre-heat ring disposed outwardly of the substrate support, one or more liners disposed outwardly of the substrate support, or one or more sidewalls of the processing chamber.

11. A processing chamber applicable for use in semiconductor manufacturing, comprising:
a lower window;
an upper window, the lower window and the upper window at least partially defining an internal volume;
a substrate support disposed in the internal volume, the substrate support comprising an outer radius and a support face; and
one or more heat sources, each heat source of the one or more heat sources aligned at an offset relative to a center of the substrate support, the offset is a ratio of the outer radius, and the ratio is 0.65 or higher.

12. The processing chamber of claim 11, wherein each of the one or more heat sources comprises an arcuate lamp having a cylindrical bulb tube and a filament having a longitudinal axis aligned at the offset.

13. The processing chamber of claim 11, wherein each heat source of the one or more heat sources is oriented nonparallel to a surface of the support face, and the processing chamber further comprises a plurality of inner heat sources disposed inwardly of the one or more heat sources, each inner heat source of the plurality of inner heat sources oriented substantially parallel to the surface of the support face.

14. The processing chamber of claim 13, wherein the ratio is 0.7 or higher.

15. The processing chamber of claim 13, wherein each heat source and each inner heat source includes a lamp configured to emit infrared radiation (IR) light.

16. The processing chamber of claim 11, wherein each heat source of the one or more heat sources is oriented at an angle relative to a surface of the support face.

17. The processing chamber of claim 16, wherein the angle is within a range of 65 degrees to 90 degrees.

18. A method of processing substrates, comprising:
heating a substrate positioned on a substrate support in a processing volume of a chamber, the heating comprising:
directing radial light radially outward relative to one or more inner heat sources and toward an inner portion of the substrate, and
directing linear light linearly relative to one or more outer heat sources and toward an outer portion of the substrate;
flowing one or more process gases over the substrate to form one or more layers on the substrate; and
exhausting the one or more process gases.

19. The method of claim 18, wherein the outer portion includes an outer edge of the substrate.

20. The method of claim 18, wherein:
the radial light is directed radially outwardly relative to a bulb of each inner heat source of the one or more inner heat sources; and
the linear light is directed linearly along a linear axis of a filament of each outer heat source of the one or more outer heat sources.
